(19) United States
(12) Patent Application Publication
(10) Pub. No.: US 2016/0218266 A1
(43) Pub. Date: Jul. 28, 2016

(54) Thermoelectric Module and Cooling Apparatus Comprising Same

(71) Applicant: LG INNOTEK CO., LTD., Seoul (KR)

(72) Inventors: Sang Gon Kim, Seoul (KR); Yong Sang Cho, Seoul (KR); Boone Won, Seoul (KR); Hyung Eui Lee, Seoul (KR)

(21) Appl. No.: 14/917,162

(22) PCT Filed: Sep. 4, 2014
(86) PCT No.: PCT/KR2014/008333

§ 371 Date: Mar. 7, 2016

(30) Foreign Application Priority Data
Sep. 6, 2013 (KR) 10-2013-0107384

(51) Int. Cl. H01L 35/02; H01L 35/18; F25B 21/02; H01L 35/32

(52) U.S. Cl. CPC H01L 35/02; H01L 35/32; H01L 35/18; F25B 21/02

(57) ABSTRACT

Embodiments of the present invention relate to a thermoelectric module used for cooling, and provide a thermoelectric module comprising: substrates facing each other; and a first semiconductor element and a second semiconductor element arranged between the substrates and electrically connected to each other, wherein the first semiconductor element and the second semiconductor element have mutually different volumes. The present invention has a structure allowing the cooling effect to be raised by having, in a unit cell comprising thermoelectric semiconductor elements, any one from among the semiconductor elements facing each other to have a volume greater than the other to enhance the rise in electrical conductivity.

### TECHNICAL FIELD

The present invention relates to a thermoelectric module used for cooling.

### BACKGROUND ART

Generally, a thermoelectric module including a thermoelectric conversion element has a structure formed as a PN junction pair in which a P-type thermoelectric material and an N-type thermoelectric material are bonded between metal electrodes. When a temperature difference is given between the PN junction pair, electric power is generated by the Seeback effect, thereby the thermoelectric element can function as an apparatus generating electric power. Further, the thermoelectric element may be used as a temperature control apparatus by the Peltier effect, in which one side of the PN junction pair is cooled while the other side is heated.

In this regard, the Peltier effect is a phenomenon that, when a DC voltage is applied from the outside, holes of the P-type material and electrons of the N-type material move, which causes heat generation and heat absorption at opposite ends of the material. The Seeback effect refers to a phenomenon that, when heat is supplied from an external heat source, electrons and holes move which causes a current flow in a material, thereby generating electricity.

Such an active cooling using the thermoelectric material is recognized as a compact and eco-friendly method because of improved the thermal stability of the element, no vibration, no noise, and no need to use a separate condenser and refrigerant. Application fields of the active cooling using the thermoelectric material may include a refrigerant-free refrigerator, an air conditioner, various micro-cooling systems, and the like, and particularly, when the thermoelectric element is attached to various kinds of memory devices, the performance of the devices can be improved since maintaining the devices at a uniform and stable temperature is possible while reducing the volume as compared to a conventional cooling method.

As a factor to measure a performance of the thermoelectric material, a ZT value of dimensionless figure of merit (hereinafter, referred to as “thermoelectric figure of merit”) defined by the following Equation 1 is used.

$$ZT = \frac{{S}^{2} σ T}{κ } \qquad [ Equation 1 ]$$

Here, S is a Seeback coefficient, G is electrical conductivity, T is absolute temperature, and κ is thermal conductivity.

Recently, methods for improving thermoelectric efficiency in various perspectives have been reported.

However, in the majority of cases, the elements formed of the P-type thermoelectric material and the N-type thermoelectric material are manufactured by a bulk-type based on the same specification even when being applied to a cooling apparatus, which actually has shown a limit to cooling efficiency due to different electrical conducting characteristics between the P-type thermoelectric material and the N-type thermoelectric material.

### DISCLOSURE

### Technical Problem

The present invention is directed to providing a thermoelectric module configured to have a structure capable of enhancing cooling efficiency by forming a volume of one of thermoelectric semiconductor elements facing each other to be greater than that of the other in a unit cell formed with the thermoelectric semiconductor elements to enhance electrical conductivity characteristics.

### Technical Solution

One aspect of the present invention provides a thermoelectric module which includes at least one unit cell having a first semiconductor element and a second semiconductor element which are electrically connected, wherein volumes of the first semiconductor element and the second semiconductor element are mutually different. In this case, the first semiconductor element may be formed of a P-type semiconductor element and the second semiconductor element may be formed of an N-type semiconductor element, and a cooling module implemented by a structure in which the volume of the N-type semiconductor element is formed to be relatively greater than that of the P-type semiconductor element is provided.

### Advantageous Effects

According to the embodiment of the present invention, by forming a volume of one of thermoelectric semiconductor elements facing each other to be greater than that of the other in a unit cell formed with the thermoelectric semiconductor elements, electrical conductivity characteristics can be improved, thereby having an effect of enhancing the cooling efficiency.

Particularly, by forming a volume of an N-type semiconductor element to be greater than that of a P-type semiconductor element facing the N-type semiconductor element by changing a diameter of a cross section or a height of the N-type semiconductor element, the thermoelectric cooling efficiency is raised, and in addition, the cross section of the thermoelectric element can be formed in a circular or an elliptical shape having a curvature to form a printed-type thick film, thereby having an effect of raising the efficiency in a manufacturing process.

### DESCRIPTION OF DRAWINGS

FIG. 1 is a conceptual view illustrating a sample of forming a thermoelectric module using a thermoelectric element.

FIGS. 2 to 13 are views illustrating configuration examples of a thermoelectric module employing a thermoelectric element according to various embodiments of the present invention.

FIGS. 14 to 17 are views illustrating experimental examples of characteristics according to various embodiments of the present invention.

### REFERENCE NUMERALS

101a, 101b: SUBSTRATE
102a, 102b: ELECTRODE
104a, 104b: THERMOELECTRIC ELEMENT (SEMICONDUCTOR ELEMENT)
110: UNIT CELL

### Modes of the Invention

Hereinafter, configurations and operations according to the present invention will be described in detail with reference to the accompanying drawings. In the description with reference to the accompanying drawings, like elements are designated by the same reference numerals regardless of drawing numbers, and duplicated descriptions thereof will be omitted. Although the terms “first,” “second,” etc. may be used herein to describe various elements, these elements should not be limited by these terms. These terms are only used to distinguish one element from another.

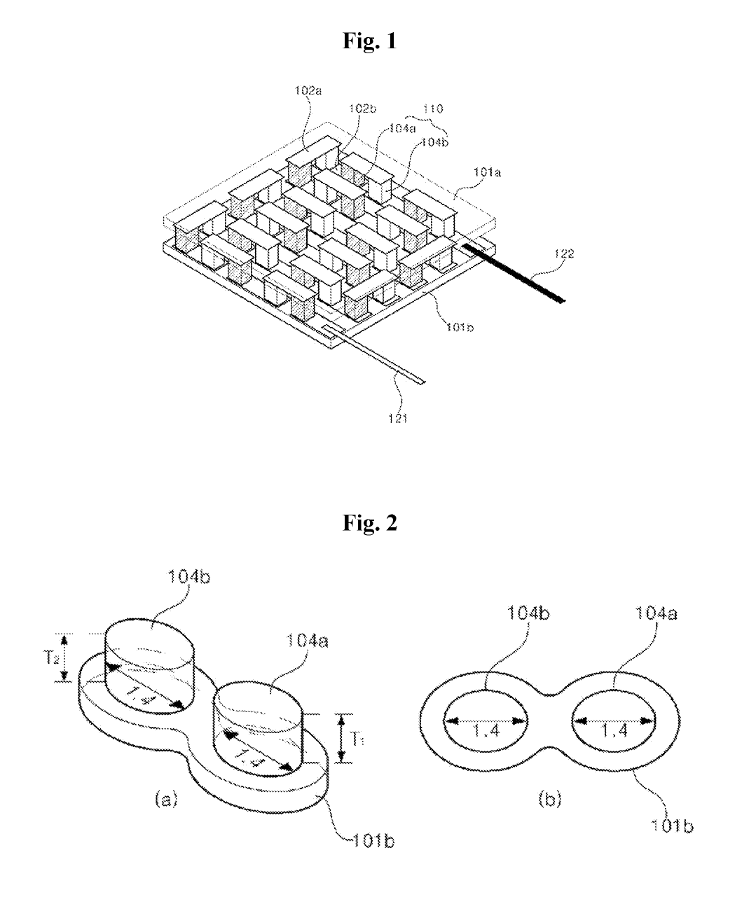

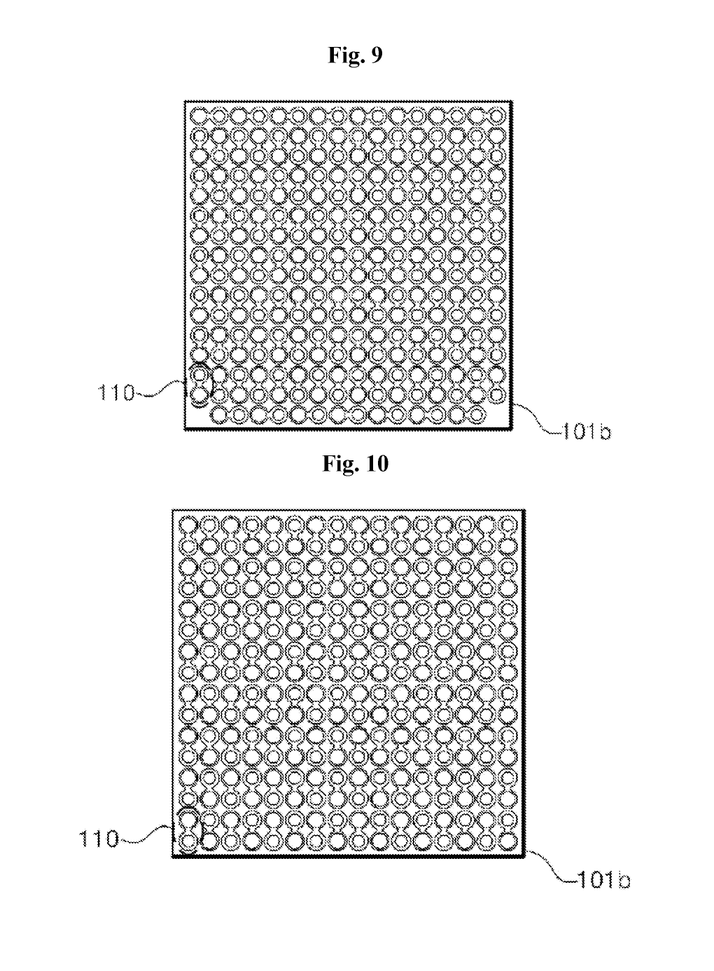

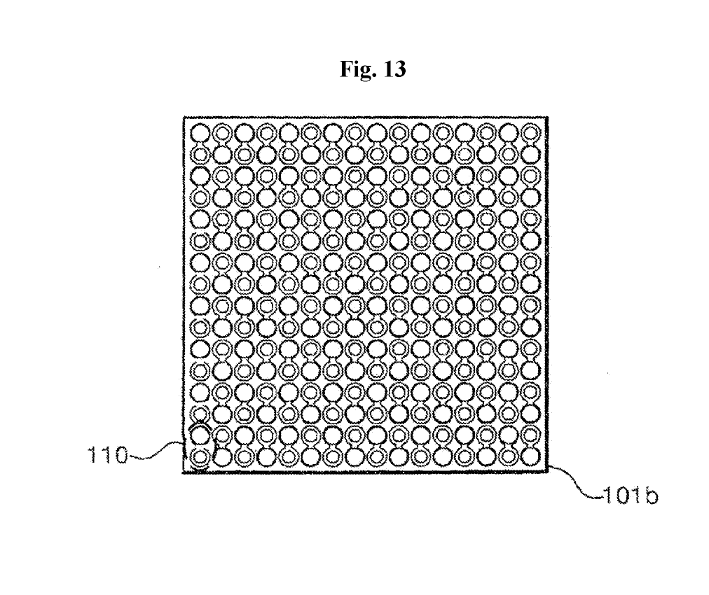

FIG. 1 is a conceptual view illustrating a thermoelectric module using a thermoelectric element, and FIGS. 2 to 13 are views illustrating implementation examples of various thermoelectric modules according to an embodiment of the present invention.

As shown in FIG. 1, generally, in the thermoelectric module employing the thermoelectric element used for cooling, semiconductor elements having different materials and characteristics from each other are disposed in pairs, each of the semiconductor elements in pairs are electrically connected by metal electrodes to form a unit cell 110, and such a structure in which a plurality of unit cells are disposed may be implemented. Particularly, in the case of the thermoelectric element forming the unit cell, one side thereof may be formed as a P-type semiconductor as a first semiconductor element 104a and an N-type semiconductor as a second semiconductor element 104b, the first semiconductor and the second semiconductor are connected with metal electrodes 102a and 102b, and a plurality of the above structures are formed, thereby implementing a Peltier effect by circuit lines 121 and 122 which supply current to the semiconductor elements through the media of the electrodes. In the thermoelectric module, as shown in FIG. 1, the first semiconductor element and the second semiconductor element facing each other form the unit cell 110 and are formed in the same shape and size, but in this case, a difference in electrical conductivity characteristics between the P-type semiconductor element and the N-type semiconductor element acts as an impeding factor which degrades the cooling efficiency. In this regard, in the present invention, the cooling performance is able to be improved by forming a volume of one of the semiconductor elements in the unit cell 110 shown in FIG. 1 to be different from the volume of the other semiconductor element facing the one.

The formation of the volumes of the semiconductor elements disposed facing each other in the unit cell to be different may be implemented by methods, on the whole, of forming entire shapes of the semiconductor elements to be different, forming a diameter of a cross section at one of the semiconductor elements to be wider than the other in the semiconductor elements having the same height, or forming heights or diameters of the cross sections of the semiconductor elements to be different in the semiconductor elements having the same shape.

Figures of the diameters of the thermoelectric semiconductor elements which are illustrated in the views and embodiments of the present invention described below are formed as examples, are not limited thereto, and may be formed in various ranges of designs including the examples.

Referring to FIGS. 2 to 4, FIG. 2(a) is a conceptual view illustrating the formation of a unit cell, and FIG. 2(b) is a top view of FIG. 2(b).

In the unit cell including a thermoelectric element illustrated in FIG. 2 according to an embodiment of the present invention, semiconductor elements having the same shape and diameter (each diameter: 1.4 mm) are disposed in a pair, but a height T2 of a second semiconductor element 104b is configured to be higher than a height T1 of a first semiconductor element 104a so that volumes of each semiconductor element are formed differently. In this case, particularly, the second semiconductor element 104b may be implemented as an N-type semiconductor element.

Particularly, as shown in the views, in the embodiment of the present invention, unlike a conventional bulk-type semiconductor element, cross sections of the first semiconductor element and the second semiconductor element form a circle, which enables forming a printed-type thick film in a design of a cylindrical shape, thereby enhancing manufacturing efficiency. The N-type semiconductor may be formed using a mixture in which main ingredient material formed of a bismuth telluride based (BiTe based) material including selenium (Se), nickel (Ni), aluminum (Al), copper (Cu), silver (Ag), lead (Pb), boron (B), gallium (Ga), tellurium (Te), bismuth (Bi), and/or indium (In) and Bi or Te corresponding to 0.001 to 1.0 wt % of the total weight of the main ingredient material are mixed. In other words, the main ingredient material is a Bi—Se—Te material, in which Bi or Te corresponding to 0.001 to 1.0 wt % of the total weight of the Bi—Se—Te is further added to form the mixture. That is, when 100 g of weight of Bi—Se—Te is input, it is preferable that Bi or Te is additionally added in the range of 0.001 g to 1.0 g. As described above, the weight range of the material added to the main ingredient material is significant in that the improvement of a ZT value cannot be expected outside the range of 0.001 wt % to 0.1 wt % as the thermal conductivity is not lowered while electric conductivity drops.

The P-type semiconductor material is preferably formed using a mixture in which a main ingredient material formed of a BiTe based material including antimony (Sb), nickel (Ni), aluminum (Al), copper (Cu), silver (Ag), lead (Pb), boron (B), gallium (Ga), tellurium (Te), bismuth (Bi), and/or indium (In) and Bi or Te corresponding to 0.001 to 1.0 wt % of the total weight of the main ingredient material are mixed. In other words, the main ingredient material is a Bi—Sb—Te material, in which Bi or Te corresponding to 0.001 to 1.0 wt % of the total weight of the Bi—Sb—Te is further added to form the mixture. That is, when 100 g of weight of Bi—Sb—Te is input, it is preferable that Bi or Te is additionally added in the range of 0.001 g to 1 g. As described above, the weight range of the material added to the main ingredient material is significant in that improvement of the ZT value cannot be expected outside the range of 0.001 wt % to 0.1 wt % as the thermal conductivity is not lowered while electrical conductivity drops.

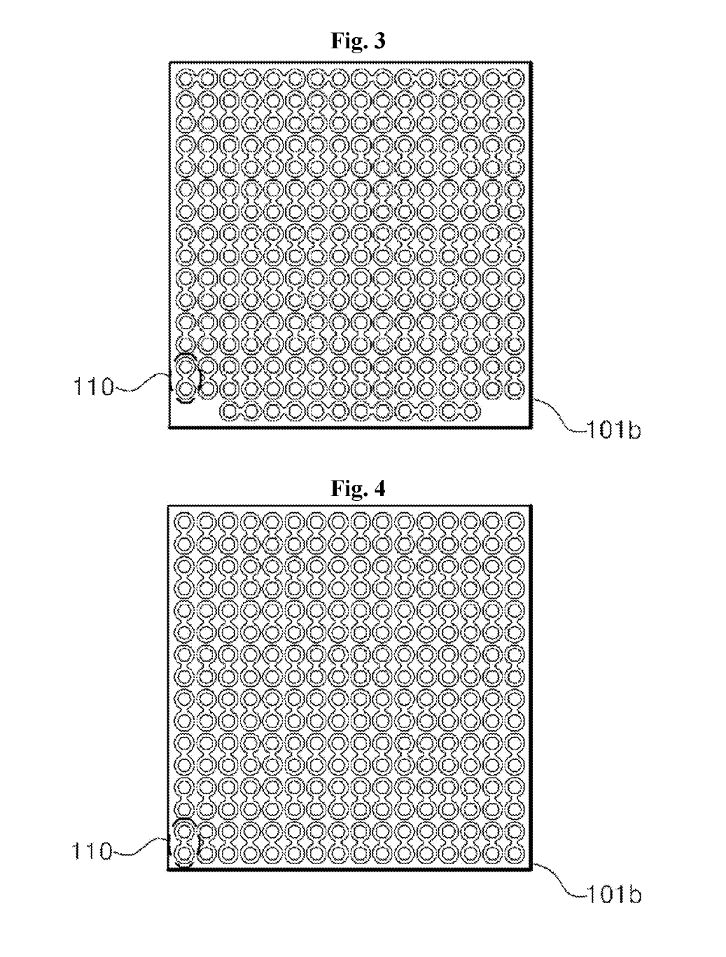

FIG. 3 is a top view of a shape in which the plurality of unit cells of FIG. 2 are formed, and FIG. 4 is a bottom view of the shape. That is, the volumes of the semiconductor elements constituting the unit cell are formed to be different, where each semiconductor element has the same diameter in a circular shape but the height of the second semiconductor element is formed to be relatively greater to increase the volume, thereby improving the thermoelectric efficiency. As a matter of course, the diameter is not limited to 1.4 mm as in the present embodiment. In this case, it is preferable that the second semiconductor element be formed as the N-type semiconductor element. In this case, a configuration in which the height difference between the first semiconductor element and the second semiconductor element is supplemented using a mechanical aid or the like may be added.

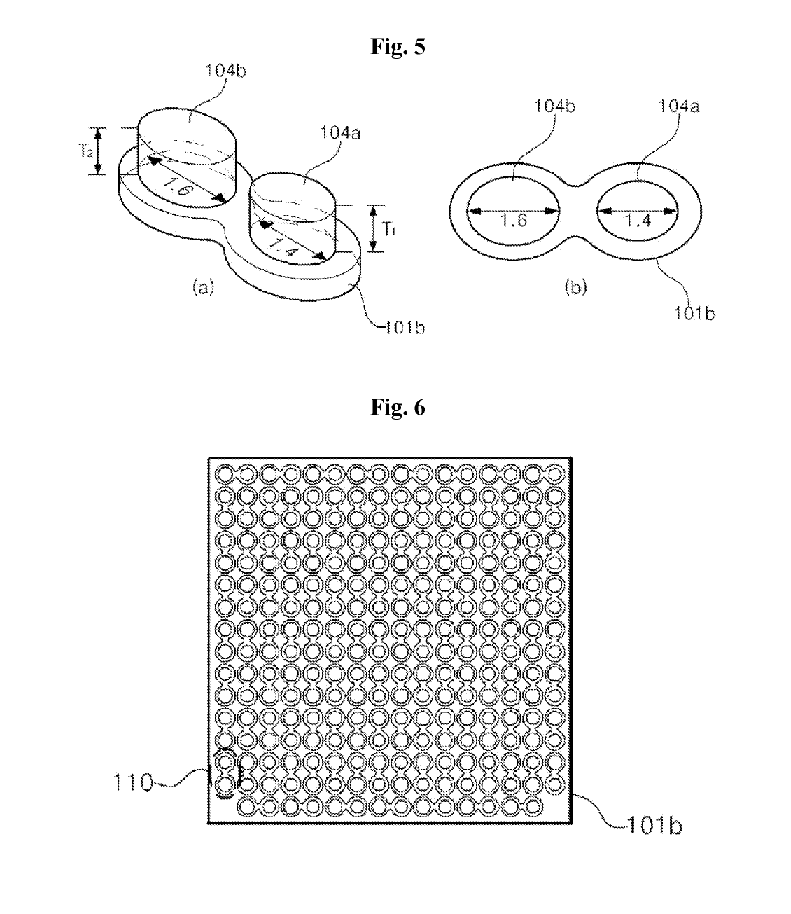

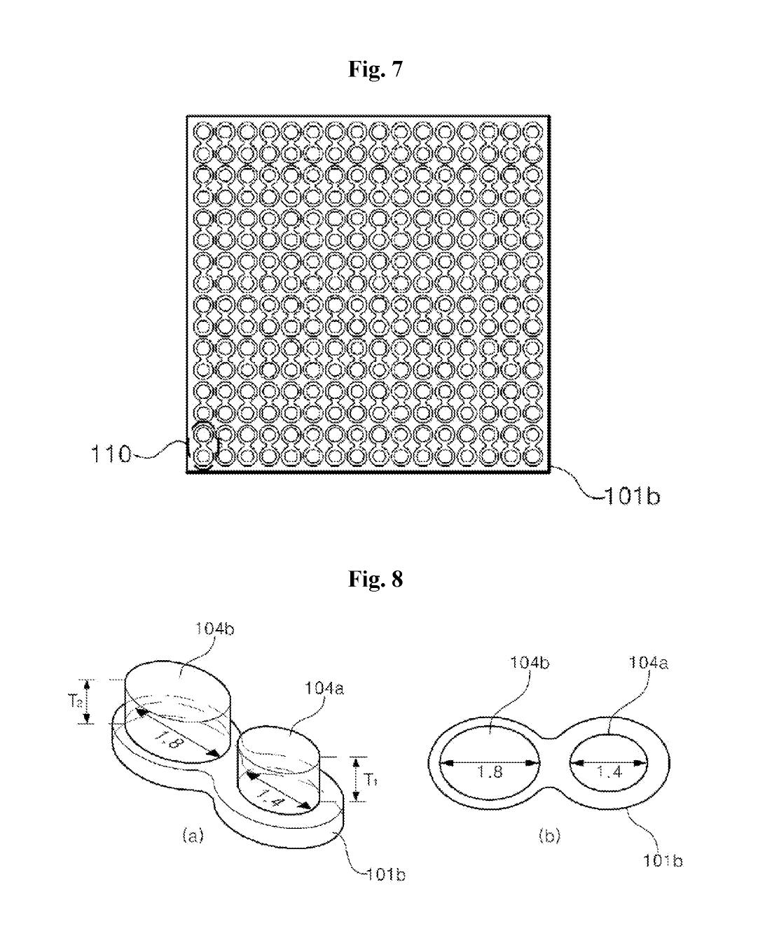

FIG. 5 illustrates the formation of different volumes by forming the diameter of the second semiconductor element 104b to be greater than the diameter of the first semiconductor element 104a. Particularly in this case, it is preferable that the second semiconductor element be formed as the N-type semiconductor element. When the first semiconductor element 104a is formed as the P-type semiconductor and the second semiconductor element 104b is formed as the N-type semiconductor, and particularly, when the height T2 of the second semiconductor element and the height T1 of the first semiconductor element are formed to be the same, by forming the diameter of a cross section of the second semiconductor element to be greater (for example, the diameter of the second semiconductor element is 1.6 mm and the diameter of the first semiconductor element is 1.4 mm.), the volume of the second semiconductor element may be formed to be relatively greater than the volume of the first semiconductor element. FIG. 6 is a top view of the shape in which the plurality of unit cells of FIG. 5 are formed, and FIG. 7 is a bottom view of the shape. That is, as a method of forming the volumes of the semiconductor elements in a pair constituting one unit cell 110 to be different from each other, the semiconductor elements in the same shape are formed to the same height, the diameter of the N-type semiconductor element is formed to be greater than that of the P-type semiconductor element to increase the volume thereof, thereby improving the thermoelectric efficiency.

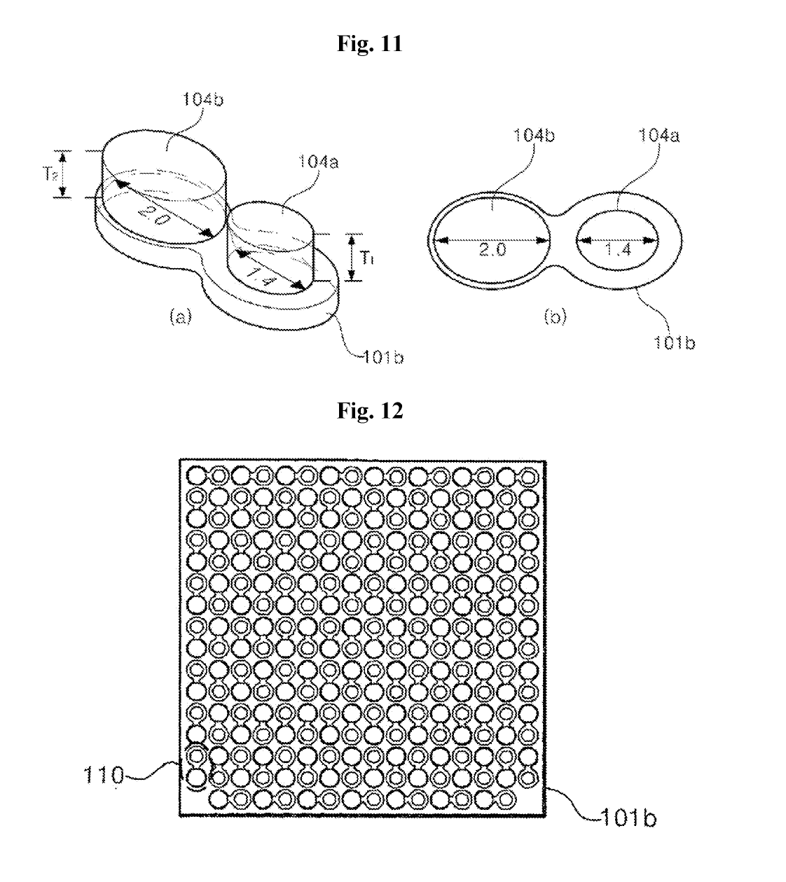

FIGS. 8 to 10 are another embodiment of forming the volumes differently by forming the diameter of the second semiconductor element 104b to be greater than the diameter of the first semiconductor element 104a, and illustrate example views in which the diameter of the second semiconductor element 104b is formed to be 1.80 mm and the diameter of the first semiconductor element 104a is formed to be 1.40 mm. FIGS. 11 to 13 are example views illustrating that the diameter of the second semiconductor element 104b is formed to be 2.0 mm and the diameter of the first semiconductor element 104a is formed to be 1.40 mm. That is, even in the case of FIGS. 8 and 11, the second semiconductor element and the first semiconductor element are formed to have the same height and shape (a cylinder or an elliptical cylinder), and the diameter of the second semiconductor element is formed to be relatively greater than the diameter of the first semiconductor element to form the volumes different from each other, and in this case, the second semiconductor element is particularly formed as the N-type semiconductor element to match the electrical conductivity characteristics thereof with the performance of the P-type semiconductor element.

In the above-described embodiment, when forming the thermoelectric semiconductor elements to have the same heights, it is preferable that a radius ratio of a horizontal cross section between the first semiconductor element and the second semiconductor element satisfy the range of 1:(1.01 to 1.5). That is, in the case that the first semiconductor element is formed as the P-type semiconductor element and the diameter of the cross section satisfy 1.4 mm, the diameter of the N-type semiconductor has a greater diameter than that and is formed in the range of 1.41 mm to 2.10 mm. This is because, in the radius ratio range of 1:1.01 of the horizontal cross section between the first semiconductor element and the second semiconductor element, it is difficult to implement the effect of improving the electrical conductivity characteristics due to little variation of the volume of the N-type semiconductor element when the ratio is less than 1.01, and when the ratio is more than 1.5, a phenomenon that the cooling performance of the thermoelectric element is conversely a little bit degraded occurs while the electrical conductivity characteristics may be satisfied.

As described in the embodiments of FIGS. 5 to 13, an experimental example is illustrated in FIG. 6 in the case that the second semiconductor element is implemented as the N-type semiconductor element, the first semiconductor element is implemented as the P-type semiconductor element, the heights of the first semiconductor element and the second semiconductor element are fixed, and a width of the second semiconductor element is increased.

[Table 1]

Characteristics of a conventional bulk-type thermoelectric element generally have the following performance.

| | Cell | Cell | Cell | Cell | Resistivity | | Delta |
|---|---|---|---|---|---|---|---|
| | width | length | area | height | (R:Ohm) = | Qc | Tmax |
| Type | (mm) | (mm) | (mm²) | (mm) | Vmax/Imax | (W) | (° C.) |
| Bulk | 2 | 2 | 4 | 1.3 | 1.1684 | 71.16 | 56.969 |

That is, in the case of the conventional bulk-type thermoelectric element, when the semiconductor elements in a pair are formed as the structure shown in FIG. 1, a P-type semiconductor and an N-type semiconductor in a rectangular shape are disposed. In this case, the resistivity was measured as 1.1684, the Qc was measured as 71.76, and the Delta Tmax (° C.) was measured as 56.965.

### Experimental Example 1

In the present experiment, variations of the resistivity, the Qc, and the Delta Tmax (° C.) were measured in the case of increasing the volume by sequentially increasing the radius of the cross section of the second semiconductor element (the N-type semiconductor) at each rate of 0.7, 0.8, 0.9, and 1.0, while the radius of the cross section of the first semiconductor element (the P-type semiconductor) was fixed to 0.7 mm. Each height of the thermoelectric elements was printed as 0.5 mm.

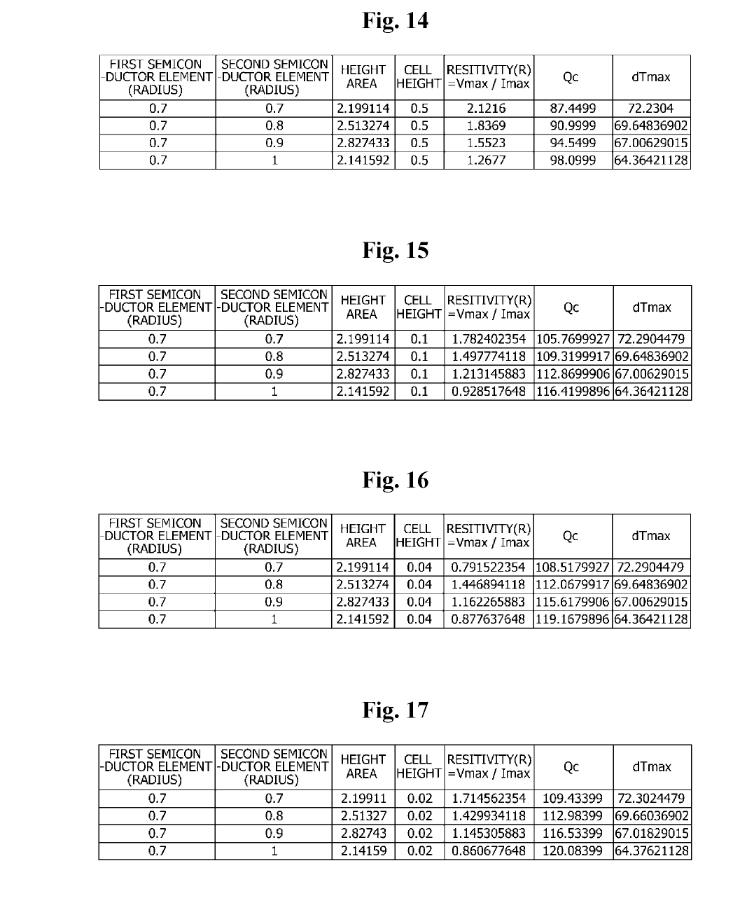

As illustrated in FIG. 14, when the radii of the first semiconductor (the P-type semiconductor) and the second semiconductor (the N-type semiconductor) are formed to be the same radius of 0.7 mm (comparative example 1), that is, when the volumes were the same, the resistivity was measured as 2.1216Ω, the Qc was measured as 87.4499 W, and the Delta T was measured as 72.2304° C.

In contrast, when the volume of the second semiconductor element (the N-type semiconductor) was increased by increasing the radius of the cross section of the second semiconductor element at each rate of 0.8, 0.9, and 1.0, the resistivity value was measured as 1.8369 Ω, 1.5523Ω, and 1.2677Ω respectively, from which it was verified that the resistivity was lowered by a maximum of 40% or more as compared to the case of the same volume as shown in comparative example 1, thereby the electrical conductivity characteristics was improved. The Qc was measured as 90.9999, 94.5499, and 98.0999 respectively, and it was verified that the Qc was improved by a maximum of 12% or more as compared to comparative example 1. In spite of the efficiency improvement, in terms of the variation of the Delta T (° C.), the Delta T (° C.) was formed within an acceptable range that the efficiency was not much different from that of the comparative example, and it was verified that it was more excellent by 10° C. as compared to the conventional bulk-type.

### Experimental Example 2

Referring to FIG. 15, in the present experiment, printing heights of the thermoelectric elements in the comparative example and experimental example were fixed to 0.1 mm, the radius of the cross section of the first semiconductor element (the P-type semiconductor) was fixed to 0.7 mm, and variations of the resistivity, the Qc, and the Delta Tmax (° C.) were measured in the case of increasing the volume by sequentially increasing the radius of the cross section of the second semiconductor element (the N-type semiconductor) at each of the rates of 0.7 (comparative example 2), 0.8, 0.9, and 1.0.

The result was similar to that when the volume of the second semiconductor element (the N-type semiconductor) was increased by increasing the radius of the cross section of the second semiconductor element at each of the rates of 0.8, 0.9, and 1.0, the resistivity was measured as 1.4977 Ω, 1.2131Ω, and 0.9285Ω respectively, which was lowering the resistivity by a maximum of 48% as compared to the resistivity of 1.7824Ω of comparative example 2, and the Qc was measured as 109.319, 112.869 and 116.419, which verified the improvement by a maximum of 10% or more as compared to 105.769 W of comparative example 2. Further, in terms of the variation of the Delta T (° C.) from comparative example 2, it was formed within an acceptable range that the efficiency was not much different from that of the comparative example, and it was verified that it was more excellent by 10° C. as compared to the bulk-type.

### Experimental Example 3

Referring to FIG. 16, in the present experiment, the printing heights of the thermoelectric elements in the comparative example and experimental example were fixed to 0.04 mm, the radius of the cross section of the first semiconductor element (the P-type semiconductor) was fixed to 0.7 mm, and variations of the resistivity, the Qc, and the Delta Tmax (° C.) were measured in the case of increasing the volume by sequentially increasing the radius of the cross section of the second semiconductor element (the N-type semiconductor) at each of the rates of 0.7 (comparative example 3), 0.8, 0.9, and 1.0.

The result was similar to that when the volume of the second semiconductor element (the N-type semiconductor) was increased by increasing the radius of the cross section of the second semiconductor element at each of the rates of 0.8, 0.9, and 1.0, the resistivity was measured as 1.4468 Ω, 1.1622Ω, and 0.8776Ω respectively, which was lowering the resistivity by a maximum of 49% as compared to the resistivity of 1.7315Ω of comparative example 3, and the Qc was measured as 112.067, 115.617 and 119.167, which verified the improvement by a maximum of 9.8% or more as compared to 108.517 W of comparative example 2. Further, in terms of the variation of the Delta T (° C.) from comparative example 2, it was formed within an acceptable range that the efficiency was not much different from that of the comparative example, and it was verified that it was more excellent by 10° C. as compared to the bulk-type.

### Experimental Example 4

Referring to FIG. 17, in the present experiment, the printing heights of the thermoelectric elements in the comparative example and experimental example were fixed to 0.02 mm, the radius of the cross section of the first semiconductor element (the P-type semiconductor) was fixed to 0.7 mm, and variations of the resistivity, the Qc, and the Delta Tmax (° C.) were measured in the case of increasing the volume by sequentially increasing the radius of the cross section of the second semiconductor element (the N-type semiconductor) at each of the rates of 0.7 (comparative example 4), 0.8, 0.9, and 1.0.

The result was similar to that when the volume of the second semiconductor element (the N-type semiconductor) was increased by increasing the radius of the cross section of the second semiconductor element at each of the rates of 0.8, 0.9, and 1.0, the resistivity was measured as 1.4299 Ω, 1.1453Ω, and 0.8606Ω respectively, which was lowering the resistivity by a maximum of 50% as compared to the resistivity of 1.7145Ω of comparative example 4, and the Qc was measured as 112.983, 116.533 and 120.083, which verified the improvement by a maximum of 9.7% or more as compared to 109.433 W of comparative example 4. Further, in terms of the variation of the Delta T (° C.) from comparative example 2, it was formed within an acceptable range that the efficiency was not much different from that of the comparative example, and it was verified that it was more excellent by 10° C. as compared to the bulk-type.

All the result of experimental examples 1 to 4 are experimental examples formed as compared to the comparative examples in the range that the ratio of the radius of the P-type semiconductor element (the first semiconductor element) to the radius of the N-type semiconductor element (the second semiconductor element) are satisfying the range of 1:(1.01˜1.50), which verifies that in any case it brings a significant improvement in terms of the resistivity, the Qc, and the Delta T (° C.) as compared to the conventional bulk-type thermoelectric element shown in Table 1. Particularly, as verified in experimental examples 1 to 4 above, the first semiconductor element and the second semiconductor element according to the embodiment of the present invention are formed by being printed in a form of a film, and the thickness is formed in the range of 0.02 mm to 0.50 mm. It is because the cooling performance as the thermoelectric element is degraded when the thickness is less than 0.02 mm, and there is little difference from the bulk-type element in terms of Qc characteristics when the thickness is more than 0.5 mm.

The detailed description of the present invention as described above has been described with reference to certain preferred embodiments thereof. However, various modifications may be made in the embodiments without departing from the scope of the present invention. The inventive concept of the present invention is not limited to the embodiments described above, but should be defined by the claims and equivalent scope thereof.

1. A thermoelectric module comprising:
substrates configured to face each other; and
a first semiconductor element and a second semiconductor element which are electrically connected to each other and interposed between the substrates,
wherein volumes of the first semiconductor element and the second semiconductor element are different from each other.

2. The thermoelectric module of claim 1, wherein the first semiconductor element and the second semiconductor element are disposed separately from each other.

3. The thermoelectric module of claim 1, wherein the first semiconductor element includes a P-type semiconductor element, and the second semiconductor element includes an N-type semiconductor element.

4. The thermoelectric module of claim 3, wherein the volume of the second semiconductor element is greater than the volume of the first semiconductor element.

5. The thermoelectric module of claim 4, wherein the first semiconductor element and the second semiconductor element have the same shape of a horizontal cross section.

6. The thermoelectric module of claim 5, wherein the shapes of the horizontal cross sections of the first semiconductor element and the second semiconductor element are a circle or an ellipse.

7. The thermoelectric module of claim 4, wherein a diameter of a horizontal cross section of the second semiconductor element is greater than a diameter of a horizontal cross section of the first semiconductor element.

8. The thermoelectric module of claim 7, wherein a radius ratio of the horizontal cross section of the first semiconductor element to the second semiconductor element is in a range of 1:(1.01 to 1.5).

9. The thermoelectric module of claim 8, wherein heights of the first semiconductor element and the second semiconductor element are the same.

10. The thermoelectric module of claim 4, wherein a height of the second semiconductor element in a vertical direction is greater than the height of the first semiconductor element.

11. The thermoelectric module of claim 4, wherein heights of the first semiconductor element and the second semiconductor element are in a range of 0.02 mm to 0.50 mm.

12. The thermoelectric module of claim 11, wherein the first semiconductor element and the second semiconductor element has a structure printed in a form of a film on any one of the substrates facing each other.

13. The thermoelectric module of claim 4, comprising a plurality of unit cells in which the first semiconductor is electronically connected to the second semiconductor as a pair.

14. The thermoelectric module of claim 4, wherein the P-type semiconductor element and the N type semiconductor element include a mixture in which Bi or Te is mixed with a main ingredient material formed of a BiTe based material.

15. The thermoelectric module of claim 14, wherein the mixture is formed by mixing a main ingredient material and additional one or more selected from Ag, Au, Pt, Cu, Ni and Al.

16. A thermoelectric apparatus comprising:
substrates configured to face each other;
unit cells each including a first semiconductor element and a second semiconductor element which are electrically connected to each other and interposed between the substrates; and
a thermoelectric module including the plurality of unit cells, wherein volumes of the first semiconductor and the second semiconductor in the unit cell are different from each other.
